(19) United States
(12) Patent Application Publication
(10) Pub. No.: US 2004/0235258 A1
(43) Pub. Date: Nov. 25, 2004

(54) Method of forming resistive structures

(76) Inventors: David Donggang Wu, Austin, TX (US); Jon D. Cheek, Austin, TX (US)

Correspondence Address: TOLER & LARSON & ABEL L.L.P., 5000 PLAZA ON THE LAKE STE 265, AUSTIN, TX, 78746, US

(21) Appl. No.: 10/440,605

(22) Filed: May 19, 2003

(51) Int. Cl. H01L 21/44; H01L 21/50; H01L 21/48

(52) U.S. Cl. 438/384; 438/382

(57) ABSTRACT

A resistive structure formed overlying a semiconductor substrate is masked with a silicide block layer to define a portion of the resistive structure that is to be unsilicided and a portion of the resistive structure to be silicided. The silicide block layer is changed to facilitate different processes.

### BACKGROUND

As a high performance semiconductor product design is manufactured in multiple fabrication lines, or on fabrication lines having processes that are to be changed, the ability to obtain modified resistance values of high precision resistors is needed to assure proper functionality across such fabrication lines having different resistor specifications, such as different sheet resistivity, measured in ohms/square.

One way of modifying the value of a resistor formed on semiconductor devices has been to change the contact locations to the resistor by supplying a new contact photo mask. By changing the contact points along a resistor, the number of squares of the resistive structure between the contacts is changed, thereby modifying the resistive value. As technology dimensions have scaled downward, the cost of contact photo masks has increased, causing such modification to become more costly.

Therefore, a method of reducing the cost of obtaining a modified resistive value would be desirable.

### FIELD OF THE INVENTION

The present disclosure relates generally to semiconductor devices, and more particularly to semiconductor devices having resistive structures.

### BRIEF DESCRIPTION OF THE DRAWINGS

The present invention may be better understood, and its numerous features, and advantages made apparent to those skilled in the art by referencing the accompanying drawings.

FIGS. 1 and 3 illustrate, in plan view, specific implementations of a semiconductor device having a resistor in accordance with the present disclosure;

FIGS. 2, 4, and 5 illustrate, in cross section, specific implementations of a semiconductor device having a resistor in accordance with the present disclosure;

FIGS. 6-8, illustrate in flow diagram form, specific methods in accordance with the present disclosure.

The use of the same reference symbols in different drawings indicates similar or identical items.

### DESCRIPTION OF THE PREFERRED EMBODIMENT(S)

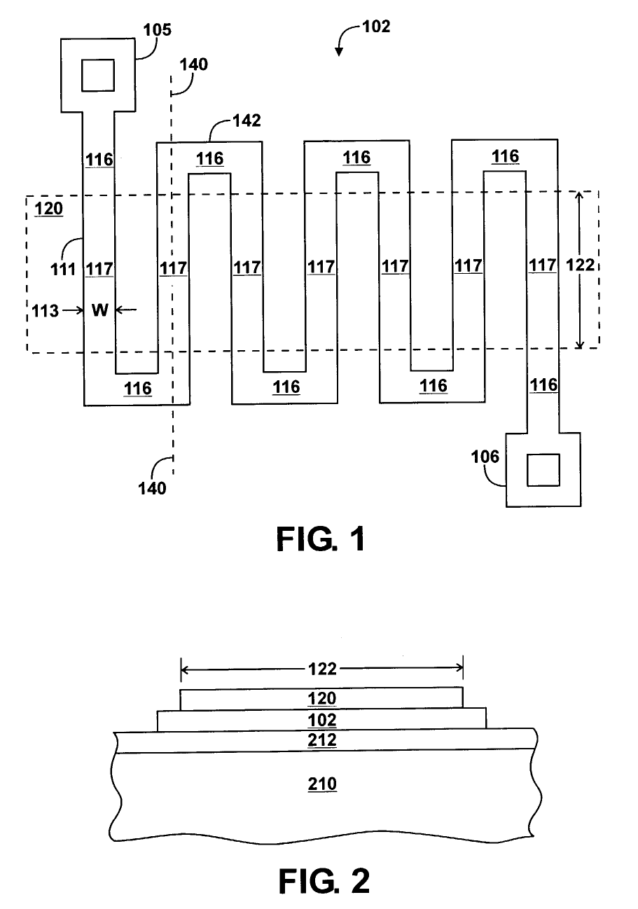

In accordance with a specific embodiment of the present disclosure, a portion of a resistive structure formed overlying a semiconductor device is masked with a silicide block layer to define a portion of the resistive structure that is to be unsilicided and a portion of the resistive structure that is to be silicided. By modifying the ratio of the resistive structure that is to be silicided as compared to the portion that is to be unsilicided, the resistive value of the resistive structure can be modified by changing a photo mask used to form the silicide block layer, which is more cost effective than changing the more costly contact layer. Specific embodiments of the present disclosure can be better understood with reference to FIGS. 1-8.

FIG. 1 illustrates a plan view of a resistive structure 102 formed over a semiconductor substrate (not illustrated in FIG. 1). The shape of resistive structure 102 is that of a serpentine structure, though it will be appreciated many alternate resistive structure shapes can be used. A vertical length of the serpentine structure making up resistive structure 102 is identified by label 111, while a horizontal length of the serpentine structure making up resistive structure 102 is identified by label 142. At each end of the resistive structure 102, there is a contact labeled 105 and 106, respectively. A total length, TL, of the resistive structure between contacts 105 and 106 defined by equation 1.

Total length=(Vertical length 111)×(Number of Vertical Runs)+(Horizontal length 112)×(Number of horizontal Runs) Equation 1

With respect to FIG. 1, the number of vertical runs is equal to seven (7), and the number of Horizontal runs is equal to six (6). It will be appreciated that the number of horizontal and vertical runs varies by design. In addition, the number of contacts associated with the resistive structure 102 of FIG. 1 can vary. For example, there may be additional contacts between the contacts 105 and 106. For purposes of discussion, the term length is to be understood as having units in terms of squares, where a square of the resistive structure 102 will be appreciated by one of ordinary skill in the art to be a function of the width W 113 of the resistive structure 102.

Typically, the resistive structure 102 is formed by etching a poly silicon layer, where the poly silicon layer has a specific sheet resistivity Rp. Subsequent to formation of the poly silicon layer, a portion of one or more segments 116 of the resistive structure 102 are silicided to have a sheet resistivity of Rs, leaving a portion of one or more segments 117 of the resistive structure as unsilicided poly silicon having the sheet resistivity Rp. A silicide block layer 120 defines the segments 116, which are silicided, and the segments 1117, which are unsilicided. The silicide block layer 120 is a masking layer that prevents the underlying portions of the resistive structure 102 from being silicided during a silication process. Specific silicide block layers may be nitrogen containing layers, such as SiN, and silicon oxynitrides, and oxygen containing layers such as silicon oxynitrides. The silicided segments 116 have a combined length L116, while the unsilicided segments 117 have a combined length of L117, where the sum of L116 and L117 is equal to the Total Length (TL) of the resistive structure 102.

When the segments 117 and 116 represent silicided poly silicon and unsilicided polysilicon, the unsilicided sheet resistivity Rp is greater than the silicided sheet resistivity Rs. While the specific embodiment discussed herein assumes that poly silicon is used, other materials having resistive properties that can be varied by modifying processes such as silicidation or other processes, may be used.

The resistive value of the resistive structure 102 (Resistance[102]), as measured between the contacts 105 and 106 is defined by equation 2

Resistance[102]=Rp*L117+Rs*L116 Equation 2.

Assuming a desired resistance, Rd, is to be implemented using the resistive structure 102, the length of the resistive structure 102 that is to be unsilicided, which is the combined length of segments 117 in FIG. 1, is found by solving equation 3 for L117 to arrive at Equation 4, as illustrated. Variables based on P1 are variables for a first process. For example, Rp[P1] is the sheet resistance of the first process P1.

$$\begin{matrix}\begin{matrix}Rd = Rp [ P1 ] * L117 + Rs [ P1 ] * L116 ; \\ Rd = Rp [ P1 ] * L117 + Rs [ P1 ] * ( TL - L117 ) ; \\ Rd = Rp [ P1 ] * L117 + Rs [ P1 ] * TL - Rs [ P1 ] * L117 ; \\ Rd = ( Rp [ P1 ] - Rs [ P1 ] ) * L117 + Rs [ P1 ] * TL ; \\ Rd - Rs [ P1 ] * TL = ( Rp [ P1 ] - Rs [ P1 ] ) * L117 ;\end{matrix} & Equation 3 \\ ( Rd - Rs [ P1 ] ) * TL ) / ( Rp [ P1 ] - Rs [ P1 ] ) = L117 ; & Equation 4\end{matrix}$$

The portion of the total length of the resistive structure 102 of FIG. 1 that is to be silicided, L116, is readily defined by equation 5.

L116[P1]=TL−L117[P1] Equation 5

Once the unsilicided length, and/or the silicided length, is known, the dimensions of silicide block layer 120, generically referred to as a masking layer, can be readily determined. FIG. 2 illustrates a cross sectional view of the resistive structure 102 of FIG. 1 at a cross section location 140. Layer 210 is a semiconductor substrate, while layer 212 represents one or more layers between the substrate 210 and the resistive structure 102. For example, layer 210 may be a single gate oxide layer, or it may represent several layers, such as dielectric and conductive layers.

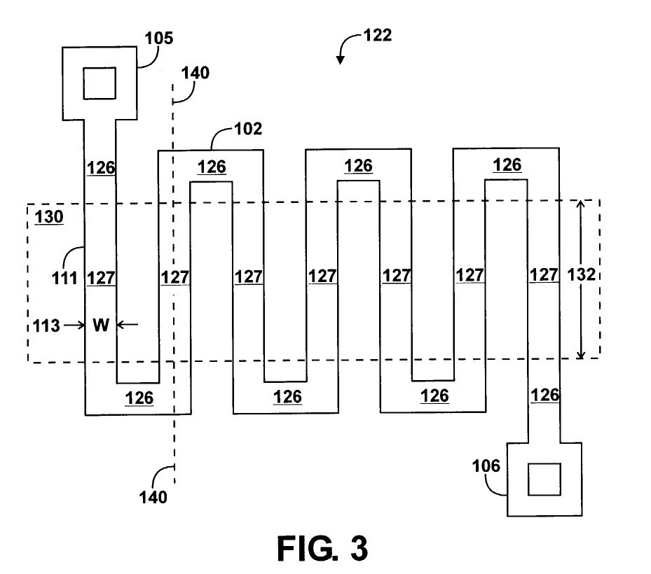

FIG. 3 illustrates a plan view of a resistive structure 122 formed over a semiconductor substrate. In one embodiment, the layouts of the resistive structure of FIGS. 3 and 2 are substantially the same, resulting in the length of resistive structure 122 being substantially identical to that of resistive structure 102, with a difference being that resistive structure 122 was formed by a different process, P2, than resistive structure 102. Because a different process was used, the sheet resistances, Rp[P2] and Rs[P2] for the process of FIG. 3, will be different than the sheet resistances, Rp[P1] and Rs[P1] of the process of FIG. 1.

Assuming the resistive structure 122 is to have the same resistance, Rd, as the resistive structure 102, equation 6 is used to determine the portion of the length of the resistive structure 122 that is to be unsilicided, which is the combined length of segments 127 in FIG. 2 (L127), and equation 7 is used to determine the portion of the length of the resistive structure 122 that is to be silicided.

L127=(Rd−Rs[P2]*TL)/(Rp[P2]−Rs[P1]); Equation 6

L126[P2]=TL−L127[P2] Equation 7

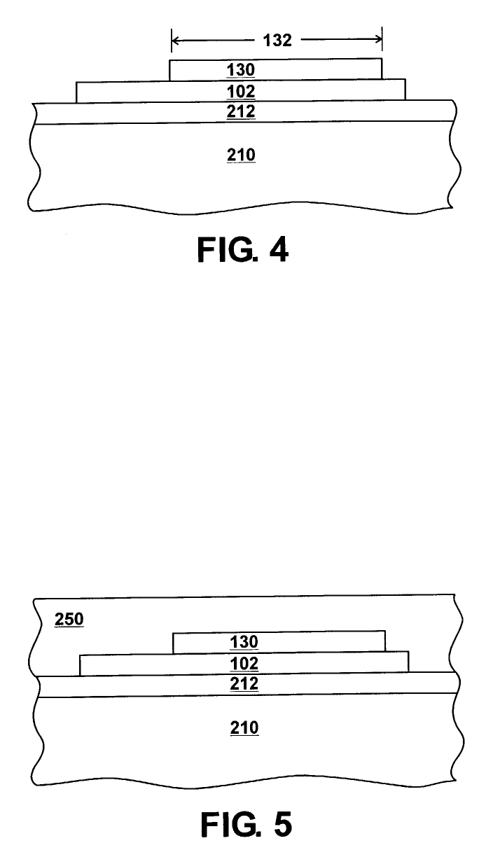

FIG. 4 illustrates a cross sectional view of the device of FIG. 3 at the cross section location 140. Note that the width 132 of the silicide block layer 120 in FIG. 3 is different than the width 122 of the silicide block layer 120 of FIG. 1. It will be appreciated that if the sheet resistances, Rp[P2] and Rs[P2] for process P2, are greater than the sheet resistances, Rp[P1] and Rp[P1] of process P2, that the combined silicided length L117 of the resistive structure 102, will be less than the combined silicided length L127 of resistive structure 122. Likewise, if the process P2 sheet resistances Rp[P2] and Rs[P2] are less than the process P1 sheet resistances Rp[P1] and Rp[P1], respectively, the combined silicided length of the resistive structure 102, L117, will be greater than the combined silicided length of the resistive structure 122.

FIG. 5 illustrates a completed semiconductor device having additional layers 250 formed over the resistive element 122 of FIG. 4. Examples of additional layers include dielectric layers, metal layers, and contact layers.

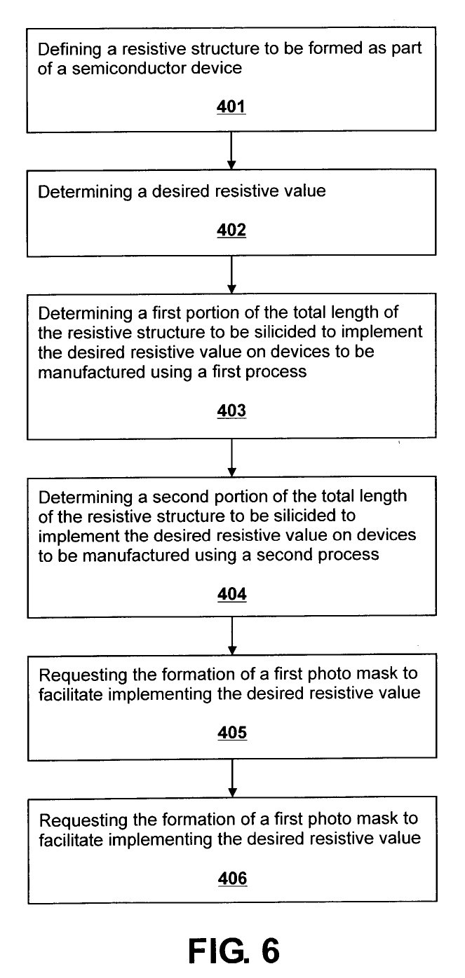

FIG. 6 illustrates a method in accordance with the present disclosure. At step 401 a resistive structure having a total length is defined to be part of a semiconductor device. Defining a resistive structure includes designing and/or forming the resistive structure.

At step 402, a desired resistive value of the resistive structure is defined.

At step 403, a determination is made as to what portion of the total length of the resistive structure to be formed by a first process is to be silicided in order to achieve the desired resistive value. It will be appreciated that determining the portion to silicided in effect also determines the portion of the resistive structure to remain unsilicided.

At step 404, a determination is made as to what portion of the total length of the resistive structure to be formed by a second process is to be silicided in order to achieve the desired resistive value. The second process may be associated with a different fabrication line than that of the first process, for example, where multiple fabrication lines are used to manufacture functionally common devices having the resistive structure. Alternatively, the first and second process can be implemented on a common fabrication line, where some aspect of the fabrication line process has been modified to result in a change of the sheet resistance of the resistive structure.

At step 405, the formation of a first photo mask is requested to facilitate formation of the resistive value on a fabrication line implementing the first process. Typically this will include providing a layer definition to a mask provider.

At step 406, the formation of a second photo mask is requested to facilitate formation of the resistive value on a fabrication line implementing the second process.

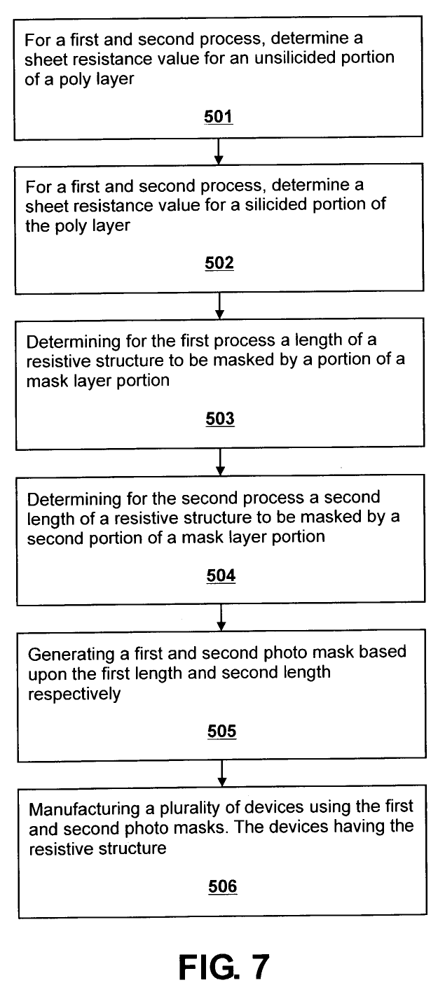

FIG. 7 illustrates a method in accordance with the present disclosure. At step 501, the sheet resistance for an un-silicided poly layer of a first and second process is determined.

At step 502, the sheet resistance for a silicided poly layer of the first and second process is determined.

At step 503, a determination is made as to the length of a resistive structure that is to be masked by a portion of a masking layer as part of a first process. In one embodiment, the masking layer is a silicide block layer.

At step 504, a determination is made as to the length of a resistive structure that is to be masked by a portion of a masking layer (silicide block layer) as part of a second process. In one embodiment, the masking layer is a silicide block layer.

At step 505, a first and second photo mask based on the lengths determined at steps 503 and 504, respectively, are generated to facilitate forming the masking layers of steps 503 and step 504.

At step 506, a plurality of devices is manufactured using the first and second photo masks to include the resistive structures.

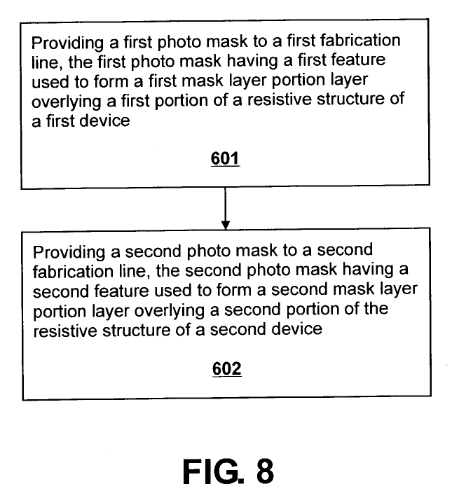

FIG. 8 illustrates a method in accordance with the present disclosure. At step 601, a photo mask is provide to a first fabrication line, where the photo mask has a feature to form a masking layer overlying a portion of a resistive structure to obtain a desired resistance. The photo mask feature may be opaque or transparent depending upon a specific process of the first fabrication line.

At step 602, a photo mask, different than the first photo mask, is provide to a second fabrication line, where the photo mask has also has a feature to form a masking layer overlying a portion of a resistive structure, typically the same or similar to the resistive structure of step 601, to obtain the desired resistance. The photo mask feature may be opaque or transparent depending upon a specific process of the second fabrication line. The second fabrication line may be a different fabrication line from the first fabrication line, i.e., both simultaneously used to produce the product to a common set of specifications, or the first and second fabrication lines may be the same fabrication line at different points of time. For example, a fabrication line having a modified process requiring a modified value of the resistive structure.

The preceding detailed description has described a method of forming resistive structures for different processes that have the same desired resistance value. In one embodiment, it will be appreciated that the actual resistance values obtained may not be identical, although it would be expected that the desired values obtained will be substantially identical, as would be expected based upon typical variations associated with the manufacture of semiconductor devices. In another embodiment, it will be further appreciated that while the term desired resistance value will typically refer to the same value for the resistive structure formed on each process, that the term may also refer to different values for each process. For example, the desired resistances may selectively vary for each process to compensate for variations in process that are not directly related to the resistive structure itself or for non-linear variation related to the resistive structure. For example, certain process variations of design components other than the resistive structure may be compensated for by having desired resistance values that differ from process to process. Also, device performance on a single fabrication line can be modified by using different photo masks to implement different resistive values.

In the preceding detailed description, reference has been made to the accompanying drawings that form a part hereof, and in which are shown by way of illustration specific embodiments in which the invention may be practiced. These embodiments and certain variants thereof, have been described in sufficient detail to enable those skilled in the art to practice the invention. It is to be understood that other suitable embodiments may be utilized and that logical, mechanical, chemical and electrical changes may be made without departing from the spirit or scope of the invention. In addition, it will be appreciated that the functional blocks shown in the figures could be further combined or divided in a number of manners without departing from the spirit or scope of the invention. The preceding detailed description is, therefore, not intended to be limited to the specific forms set forth herein, but on the contrary, it is intended to cover such alternatives, modifications, and equivalents, as can be reasonably included within the spirit and scope of the appended claims.

What is claimed is:

1. A method of forming a plurality of semiconductor devices comprising:
defining a resistive structure to be formed as part of a semiconductor device, the resistive structure comprising a total length;
determining a desired resistive value;
determining a first portion of the total length of the resistive structure to be silicided to implement the desired resistive value on a first plurality of devices to be manufactured using a first process; and
determining a second portion of the total length of the resistive structure to be silicided to implement the desired resistive value on a second plurality of devices to be manufactured using a second process.

2. The method of claim 1, wherein determining the first portion of the total length comprises the first portion having a first length, and determining the second portion of the total length comprises the second portion having a second length, wherein the first length represents a longer length than the second length when the first process has a higher sheet resistance than the second process.

3. The method of claim 1, wherein determining the first portion of the total length comprises the first portion overlying a first length of the total length, and determining the second portion comprises the second portion overlying a second length of the total length, wherein the first length represents a shorter length than the second length when the first process has a lower sheet resistance than the second process

4. The method of claim 1, wherein the second process is to be implemented on a different fabrication line than the first process.

5. The method of claim 4, wherein the second process is implemented in simultaneously in time with the first process.

6. The method of claim 1, wherein the second process is to be implemented on a same fabrication line as the first process.

7. The method of claim 1, further comprising:
requesting the formation of a first photo mask having a first feature used to define a first masking layer to overly a third portion of the total length of the resistive structure having a third length, where a sum of the first length and the third length is equal to the total length; and
requesting the formation of a second photo mask having a second feature used to define a second masking layer to overly a fourth portion of the total length of the resistive structure having a fourth length, where a sum of the second length and the fourth length is equal to the total length.

8. The method of claim 7, wherein the first masking layer is to comprise a nitride.

9. The method of claim 1, wherein the first masking layer is to comprise an oxide.

10. The method of claim 1, wherein defining the resistive structure comprises defining the resistive structure to comprise a first contact and a second contact to the resistive structure, wherein the desired resistive value is measured between the first contact and the second contact.

11. A method of forming a plurality of semiconductor devices comprising:
providing a first photo mask having a first feature to form a first masking layer overlying a first portion of a resistive structure of a first device, wherein the first feature is used to define an actual resistance value of the resistive structure on the first device; and
providing a second photo mask having a second feature to form a second masking layer overlying a second portion of the resistive structure of a second device, wherein the second feature is used to define an actual resistance value of the resistive structure on the second device.

12. A method of forming a plurality of semiconductor devices having a resistive structure using a plurality of processes comprising:
determining, for a first process, a sheet resistance value Rp1 for an unsilicided portion of a poly layer, and a sheet resistance value Rs1 for a silicided portion of the poly layer;
determining, for the first process, a first length L1 of the first resistive structure to be masked by a masking layer based on an equation
L1=(DR1−(LT1*Rp1)/(Rs1+Rp1), where LT1 is a total length of the resistive element, and DR is a desired resistance value of the first resistive structure;
determining, for a second process, a sheet resistance value Rp2 for an unsilicided portion of a poly layer, and a sheet resistance value Rs2 for a silicided portion of the poly layer;
determining, for the second process, a second length L2 of the second resistive structure to be masked by a second masking layer based on an equation
L2=(DR2−(LT2*Rp2)/(Rs2+Rp2), where LT2 is a total length of the second resistive structure and DR2 is a desired resistance value of the second resistive structure.

13. The method of claim 12, wherein DR1 and DR2 are substantially the same resistance value.

14. The method of claim 12, wherein DR1 and DR2 are different resistance values.

15. The method of claim 14, wherein a difference between the desired resistance values of DR1 and DR2 is to compensate for process variations between the first and second process.

16. The method of claim 15, wherein the process variations comprise variations between semiconductor structures, other than the first and second resistive structure, formed using the first and second process, respectively.

17. The method of claim 15, wherein the process variations comprise non-linear variations between the first and second resistive structure.

18. The method of claim 12, wherein the total length of the second resistive structure LT2 and the total length first resistive structure LT1 are substantially the same length.

19. The method of claim 12, wherein the total length of the second resistive structure LT2 is different than the total length of the first resistive structure LT1.

20. A method of forming a plurality of semiconductor devices having a resistive structure using a plurality of processes comprising:
forming a first semiconductor device comprising a first resistive element with a first silicide block layer overlying a first length of the resistive element; and
forming a second semiconductor device comprising a second resistive element with a second silicide block layer overlying a second length of the resistive element, wherein the first and second semiconductor devices have substantially the same functional specification and the first resistive element corresponds to the second resistive element.
